(19) United States
(12) Patent Application Publication
(10) Pub. No.: US 2011/0239092 A1
(43) Pub. Date: Sep. 29, 2011

(54) MEMORY SYSTEM

(76) Inventor: Koji HORISAKI, Yokohama-shi (JP)

(21) Appl. No.: 12/883,528

(22) Filed: Sep. 16, 2010

(30) Foreign Application Priority Data
Mar. 24, 2010 (JP) 2010-068435

(51) Int. Cl. H03M 13/05; G06F 11/10

(52) U.S. Cl. 714/773; 714/E11.034

(57) ABSTRACT

According to one embodiment, a memory system includes a semiconductor memory, a converter configured to convert an input data input from the semiconductor memory into a log likelihood ratio based on a conversion function, a conversion function optimizing unit configured to optimize the conversion function used for the converter, and a decoding operation unit configured to input the log likelihood ratio output from the converter to execute a decoding operation of an error correcting code. The conversion function optimizing unit optimizes the conversion function based on information related to a number of times of using the semiconductor memory.

### CROSS-REFERENCE TO RELATED APPLICATIONS

This application is based upon and claims the benefit of priority from Japanese Patent Application No. 2010-068435, filed Mar. 24, 2010; the entire contents of which are incorporated herein by reference.

### FIELD

Embodiments described herein relate generally to a memory system.

### BACKGROUND

For example, error correction in decoding is important in a memory system including a semiconductor memory such as a NAND memory and a controller of the semiconductor memory. In the foregoing error correction, processing using a soft decision value has attracted interests (e.g., see Jpn. Pat. Appln. KOKAI Publication No. 2008-59679).

However, according to a conventional method using the foregoing soft decision value, a change of the threshold voltage distribution of a semiconductor memory resulting from an aged-based change has not been taken into consideration. For this reason, a sufficient decoding performance is not necessarily obtained.

### BRIEF DESCRIPTION OF THE DRAWINGS

FIG. 1 is a block diagram showing the configuration of a memory system according to a first embodiment;

FIG. 2 is a view to explain the principle of a first embodiment;

FIG. 3 is a block diagram showing the configuration of an error checking and correction unit of a memory system according to a first embodiment;

FIG. 4 is a block diagram showing the configuration of an error checking and correction unit of a memory system according to a second embodiment;

FIG. 5 is a block diagram showing the configuration of an error checking and correction unit of a memory system according to a third embodiment;

FIG. 6 is a block diagram showing the configuration of an error checking and correction unit of a memory system according to a fourth embodiment;

FIG. 7 is a block diagram showing the configuration of an error checking and correction unit of a memory system according to a fifth embodiment;

FIG. 8 is a block diagram showing the configuration of an error checking and correction unit of a memory system according to a sixth embodiment; and

FIG. 9 is a block diagram showing the configuration of an error checking and correction unit of a memory system according to a seventh embodiment.

### DETAILED DESCRIPTION

In general, according to one embodiment, there is provided a memory system comprising: a semiconductor memory; a converter configured to convert an input data input from the semiconductor memory into a log likelihood ratio based on a conversion function; a conversion function optimizing unit configured to optimize the conversion function used for the converter; and a decoding operation unit configured to input the log likelihood ratio output from the converter to execute a decoding operation of an error correcting code, wherein the conversion function optimizing unit optimizes the conversion function based on information related to a number of times of using the semiconductor memory.

Hereinafter, various embodiments will be described below with reference to the accompanying drawings.

### First Embodiment

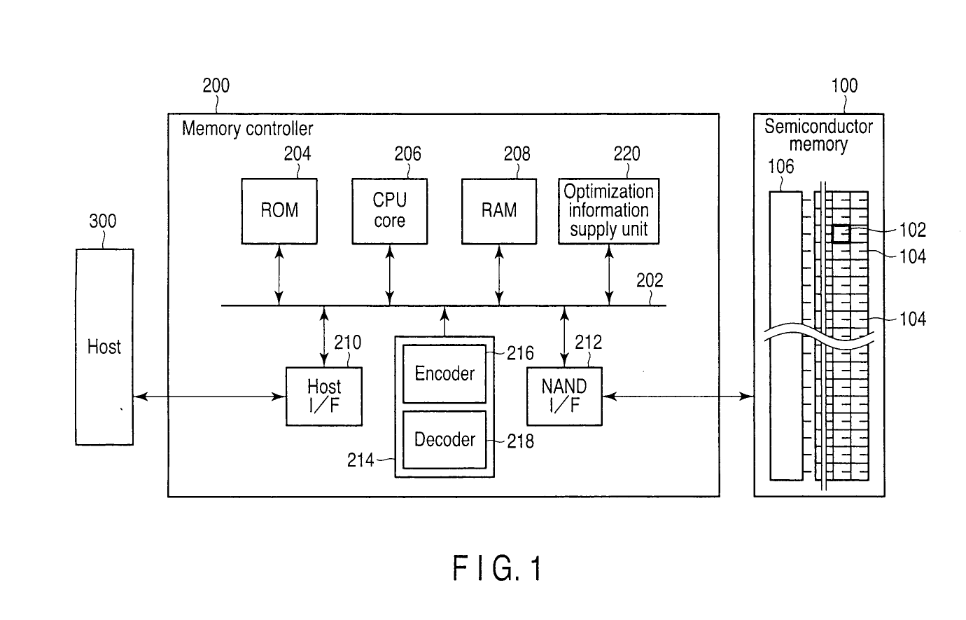

FIG. 1 is a block diagram showing the configuration of a memory system according to a first embodiment.

A memory system shown in FIG. 1 includes a nonvolatile semiconductor memory 100 and a memory controller 200. The memory system has the configuration capable of performing a data exchange with a host 300 such as a personal computer.

According to this embodiment, a NAND flash memory (NAND memory) is used as the semiconductor memory 100. Specifically, in the semiconductor memory 100, a memory cell 102 is connected with a word line 104 so that a voltage is applied to each memory cell 102 from a word line controller 106 by way of a word line 104. Each memory cell comprises a multiple-valued memory.

The memory controller 200 includes a ROM 204, a CPU core 206, a RAM 208, a host interface (I/F) 210, a NAND interface (I/F) 212, an error checking and correction unit (ECC unit) 214 and an optimization information supply unit 220. The foregoing elements are connected by way of a bus 202. The ECC unit 214 includes an encoder 216 and a decoder 218.

The memory controller 200 executes a data exchange with the host 300 by way of a host interface 210 based on the CPU core 206. Further, the controller 200 executes a data exchange with the semiconductor memory 100 by way of the NAND interface 212. Address management of the semiconductor memory 100 is performed by firmware of the CPU core 206. In addition, the control of the whole of the memory system is carried out by the firmware of the CPU core 206 in accordance with a command input from the host 300. The ROM 204 is stored with a control program of the memory system. The RAM 208 is stored with an address conversion table required for address management.

The foregoing ECC unit 214 has an encoder 216 and a decoder 218. Specifically, the encoder 216 generates an error correcting code when data is stored, and supplies the code. The decoder 218 decodes a coded data when data is read. The ECC unit 214 employs error correcting coding and decoding based on a soft decision value.

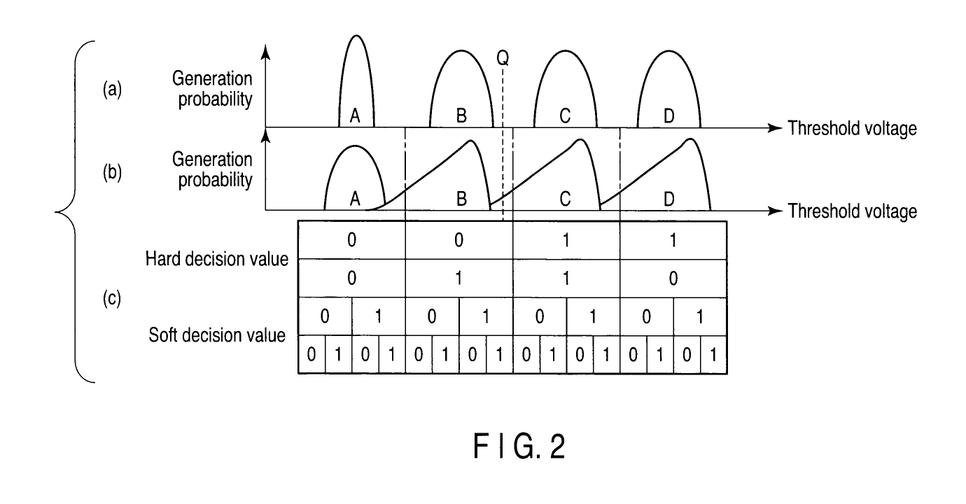

FIG. 2 is a view to explain the principle of this embodiment.

FIG. 2(a) is a graph showing a generation probability characteristic when a memory cell is manufactured (delivered). FIG. 2(b) is a graph showing a generation probability characteristic of a memory cell after elapsed for a long time from manufacture or after executing a large number of read/write times. FIG. 2(a) and FIG. 2(b) show a four-valued nonvolatile memory cell. FIG. 2(c) is a table showing a hard decision value and a soft decision value in a memory cell.

As shown from FIG. 2, a big change is seen in the generation probability characteristic between cases of FIG. 2(a) and FIG. 2(b). For example, the generation probability characteristic explanation will be explained on the assumption that the threshold value is positioned on the point Q in FIG. 2. Specifically, according to the case of FIG. 2(a), the point Q is nearest to a value “B”; therefore, there is a high possibility that a memory cell is stored with the value “B”. On the other hand, according to the case of FIG. 2(b), there is a high possibility that a memory cell is stored with a value “C”. However, even if a soft decision value is considered, in both cases of FIG. 2(a) and FIG. 2(b), the point Q is determined as having a high possibility of a value “B”. In other words, the following problem arises. Namely, according to the case of FIG. 2(b), the point Q inherently has a high possibility of being a value “C”; nevertheless, it is determined that the point Q of the case of FIG. 2(b) has a high possibility of a value “B”. This embodiment has been made in order to solve the foregoing problem.

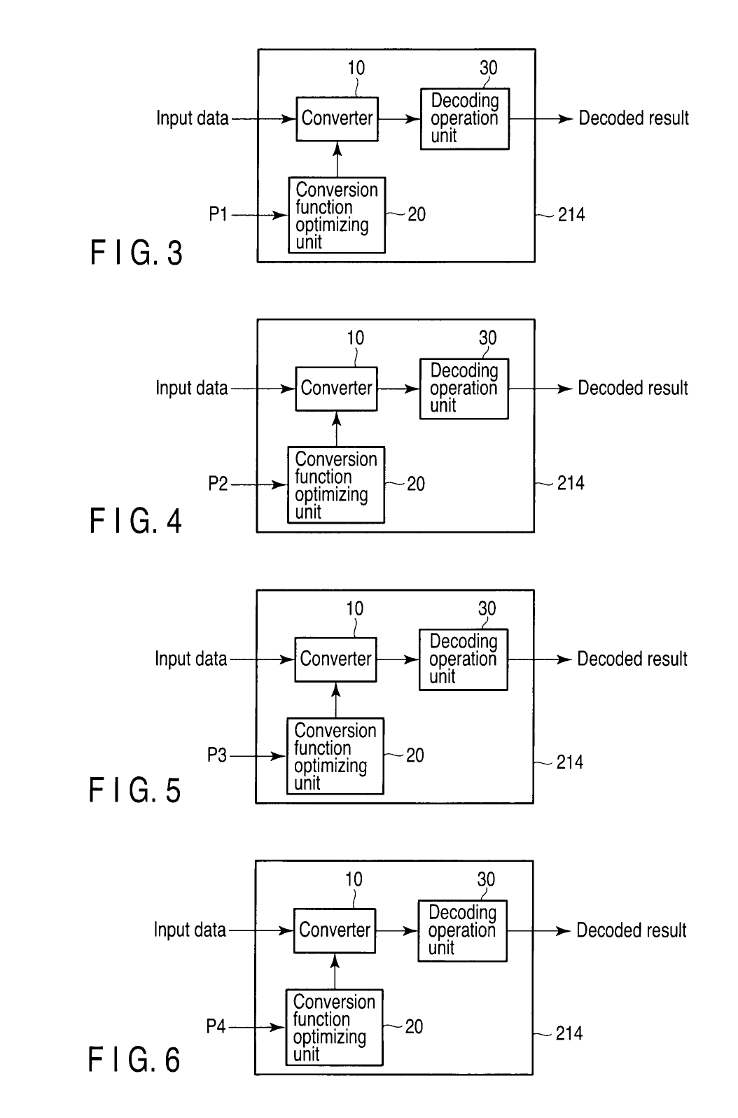

FIG. 3 is a block diagram showing the configuration of an error checking and correction unit (ECC unit) 214 of a memory system according to this first embodiment.

The ECC unit 214 shown in FIG. 3 includes a converter 10, a conversion function optimizing unit 20 and a decoding operation unit 30. Specifically, the converter 10 converts an input data input from the semiconductor memory 100 of FIG. 1 into a log likelihood ratio (LLR) based on a predetermined conversion function. The conversion function optimizing unit 20 optimizes a conversion function used for the converter 10. The decoding operation unit 30 inputs a log likelihood ratio output from the converter 10 to execute a decoding operation of an error correction code. Hereinafter, the explanation will be further additionally made.

For example, the input data shown in FIG. 3 is equivalent to a hard decision value and a soft decision value shown in FIG. 2(c). For example, according to the case of the point Q shown in FIG. 2, an input data has the following bit-string, that is, (0111) in the order from the upper bit of a hard decision value. As already described, the case of FIG. 2(a), that is, when a memory cell is manufactured (delivered), the probability that the point Q is a value “B” is high. On the other hand, the case of FIG. 2(b), that is, after the memory cell has elapsed for a long time from manufacture or after it has executed a large number of write/read operations, the probability that the point Q is a value “C” is high. Therefore, it is not suitable that the value of a log likelihood ratio output from the converter 10 is the same in both cases of FIG. 2(a) and FIG. 2(b). However, the input data is (0111) in any cases of FIG. 2(a) and FIG. 2(b). For this reason, if the content of the converter 10 has no change in both cases of FIG. 2(a) and FIG. 2(b), the value of a log likelihood ratio output from the converter 10 is the same in any cases of FIG. 2(a) and FIG. 2(b).

So, according to this embodiment, a conversion function used for the converter 10 is optimized by the conversion function optimizing unit 20. Specifically, according to this embodiment, a conversion function is optimized based on information related to the number of times of using a semiconductor memory 100. In this embodiment, the foregoing number of times of using a semiconductor memory 100 means the total number totalizing the number of times of data writes to a semiconductor memory 100 and the number of times of data reads from the same. In this case, only one of the foregoing two numbers of times may be employed. Namely, the number of times of data writes to a semiconductor memory 100 may be used as the number of times of using a semiconductor memory 100. Moreover, the number of times of data read from a semiconductor memory 100 may be used as the number of times of using a semiconductor memory 100. The foregoing optimization of a conversion function used for the converter 10 will be explained below.

The conversion function optimizing unit 20 is supplied with information P1 related to the number of times of using a semiconductor memory 100. As seen from the foregoing description, the generation probability characteristic shown in FIG. 2(a) and FIG. 2(b) changes in accordance with the number of times of using a semiconductor memory 100. So, the conversion function optimizing unit 20 optimizes a conversion function (conversion characteristic) of the converter 10 in accordance with the number of times of using a semiconductor memory 100. Specifically, the conversion function optimizing unit 20 is previously provided with a plurality of conversion tables. Further, the optimal conversion table for the converter 10 is set in accordance with the number of times of using a semiconductor memory 100. The relationship between input data (e.g., four-bit data comprising hard and soft decision values shown in FIG. 2(c)) and a log likelihood ratio is set to the conversion table. For example, according to the example of FIG. 2, in each conversion table, 16 log likelihood ratios are set for 16 four-bit input data, respectively. Concerning the point Q of FIG. 2, input data is (0111), and different log likelihood ratio is set in accordance with information related to the number of times of using a semiconductor memory 100. For example, when the input data is (0111), in the case of FIG. 2(a), a log likelihood ratio is set such that a probability having a value “B” is 0.7. Moreover, in the case of FIG. 2(b), a log likelihood ratio is set such that a probability having a value “B” is 0.2.

As described above, according to the configuration shown in FIG. 3, the optimal conversion table for the converter 10 is set in accordance with the number of times of using a semiconductor memory 100. Therefore, the decoding operation unit 30 inputs a suitable log likelihood ratio to accurately execute a decoding operation of an error correcting code. As a result, the decoding operation unit 30 outputs an accurate decoded result.

As can be seen from the foregoing description, according to this embodiment, the optimal conversion table for the converter 10 is set in accordance with the number of times of using a semiconductor memory 100. Then, input data from the semiconductor memory 100 is converted to a suitable log likelihood ratio. In general, there is a correlation between a generation probability of a read value from a memory and the number of times of using a memory. For this reason, the memory system of this embodiment is used, and thereby, it is possible to input a suitable log likelihood ratio to the decoding operation unit 30, and to accurately execute a decoding operation of an error correcting code. Therefore, a sufficient decoding performance is obtained. Moreover, according to this embodiment, the optimal conversion table (conversion function) for the converter 10 is set before decoding; therefore, this serves to reduce processing time and energy consumption.

### Second Embodiment

FIG. 4 is a block diagram showing the configuration of an error checking and correction unit (ECC unit) 214 of a memory system according to this second embodiment. In this case, the whole configuration of the memory system is the same as shown in FIG. 1. Basic matters described in FIG. 2 apply to this second embodiment. Moreover, the basic configuration shown in FIG. 4 is the same as FIG. 3. Others, basic matters described in the first embodiment apply to this second embodiment. Therefore, the explanation about matters described in the first embodiment is omitted.

According to this embodiment, a conversion function optimizing unit 20 is supplied with information P2 related to elapsed time after a semiconductor memory 100 is manufactured. As seen from the foregoing description, the generation probability characteristic shown in FIGS. 2(a) and 2(b) changes in accordance with elapsed time after a semiconductor memory 100 is manufactured. So, the conversion function optimizing unit 20 optimizes a conversion function (conversion characteristic) of a converter 10 in accordance with elapsed time after a semiconductor memory 100 is manufactured. Specifically, the conversion function optimizing unit 20 is previously provided with a plurality of conversion tables as well as the first embodiment. Further, the optimal conversion table for the converter 10 is set in accordance with elapsed time after a semiconductor memory 100 is manufactured. The detailed configuration of the conversion table is the same as the first embodiment.

As described above, according to this embodiment, the optimal conversion table for the converter 10 is set in accordance with elapsed time after a semiconductor memory 100 is manufactured. Then, input data from the semiconductor memory 100 is converted to a suitable log likelihood ratio. In general, there is a correlation between a generation probability of a read value from a memory and the elapsed time after a memory is manufactured. For this reason, the memory system of this embodiment is used, and thereby, it is possible to input a suitable log likelihood ratio to a decoding operation unit 30, and to accurately execute a decoding operation of an error correcting code. Therefore, a sufficient decoding performance is obtained. Moreover, according to this embodiment, the optimal conversion table (conversion function) for the converter 10 is set before decoding as well as the first embodiment; therefore, this serves to reduce processing time and energy consumption.

### Third Embodiment

FIG. 5 is a block diagram showing the configuration of an error checking and correction unit (ECC unit) 214 of a memory system according to this third embodiment. In this case, the whole configuration of the memory system is the same as shown in FIG. 1. Basic matters described in FIG. 2 apply to this third embodiment. Moreover, the basic configuration shown in FIG. 5 is the same as FIG. 3. Others, basic matters described in the first embodiment apply to this third embodiment. Therefore, the explanation about matters described in the first embodiment is omitted.

According to this embodiment, a conversion function optimizing unit 20 is supplied with information P3 related to elapsed time after write to a semiconductor memory 100 is carried out. As seen from the foregoing description, the characteristic of a semiconductor memory 100 has an age-based change. Therefore, the generation probability characteristic shown in FIGS. 2(a) and 2(b) changes in accordance with elapsed time after write to a semiconductor memory 100 is carried out. So, the conversion function optimizing unit 20 optimizes a conversion function (conversion characteristic) of a converter 10 in accordance with elapsed time after write to a semiconductor memory 100 is carried out. Specifically, the conversion function optimizing unit 20 is previously provided with a plurality of conversion tables as well as the first embodiment. Further, the optimal conversion table for the converter 10 is set in accordance with elapsed time after write to a semiconductor memory 100 is carried out. The detailed configuration of the conversion table is the same as the first embodiment.

As described above, according to this embodiment, the optimal conversion table for the converter 10 is set in accordance with elapsed time after write to a semiconductor memory 100 is carried out. Then, input data from the semiconductor memory 100 is converted to a suitable log likelihood ratio. In general, there is a correlation between a generation probability of a read value from a memory and the elapsed time after write to a memory is carried out. For this reason, the memory system of this embodiment is used, and thereby, it is possible to input a suitable log likelihood ratio to a decoding operation unit 30, and to accurately execute a decoding operation of an error correcting code. Therefore, a sufficient decoding performance is obtained. Moreover, according to this embodiment, the optimal conversion table (conversion function) for the converter 10 is set before decoding as well as the first embodiment; therefore, this serves to reduce processing time and energy consumption.

### Fourth Embodiment

FIG. 6 is a block diagram showing the configuration of an error checking and correction unit (ECC unit) 214 of a memory system according to this fourth embodiment. In this case, the whole configuration of the memory system is the same as shown in FIG. 1. Basic matters described in FIG. 2 apply to this fourth embodiment. Moreover, the basic configuration shown in FIG. 6 is the same as FIG. 3. Others, basic matters described in the first embodiment apply to this fourth embodiment. Therefore, the explanation about matters described in the first embodiment is omitted.

According to this embodiment, a conversion function optimizing unit 20 is supplied with information P4 related to the number of write times until a desired write voltage is obtained when write to a semiconductor memory 100 is carried out. As seen from the foregoing description, the characteristic of a semiconductor memory 100 has an age-based change. For this reason, the characteristic of a semiconductor memory 100 is reduced due to an age-based change. As a result, there is a need to frequently carry out a write operation (retry) until a desired write voltage (desired threshold voltage) is obtained when write is carried out. Therefore, there is a correlation between the number of write times when write is carried out (number of retry times) and the generation probability characteristic shown in FIGS. 2(a) and 2(b). So, the conversion function optimizing unit 20 optimizes a conversion function (conversion characteristic) of a converter 10 in accordance with the number of write times until a desired write voltage is obtained when write is carried out with respect to a semiconductor memory 100. Specifically, the conversion function optimizing unit 20 is previously provided with a plurality of conversion tables as well as the first embodiment. Further, the optimal conversion table for the converter 10 is set in accordance with the foregoing number of write times. The detailed configuration of the conversion table is the same as the first embodiment.

As described above, according to this embodiment, the optimal conversion table for the converter 10 is set in accordance with the number of write times until a desired write voltage is obtained when write is carried out with respect to a semiconductor memory 100. Then, input data from the semiconductor memory 100 is converted to a suitable log likelihood ratio. In general, there is a correlation between a generation probability of a read value from a memory and the foregoing number of write times. For this reason, the memory system of this embodiment is used, and thereby, it is possible to input a suitable log likelihood ratio to a decoding operation unit 30, and to accurately execute a decoding operation of an error correcting code. Therefore, a sufficient decoding performance is obtained. Moreover, according to this embodiment, the optimal conversion table (conversion function) for the converter 10 is set before decoding as well as the first embodiment; therefore, this serves to reduce processing time and energy consumption.

### Fifth Embodiment

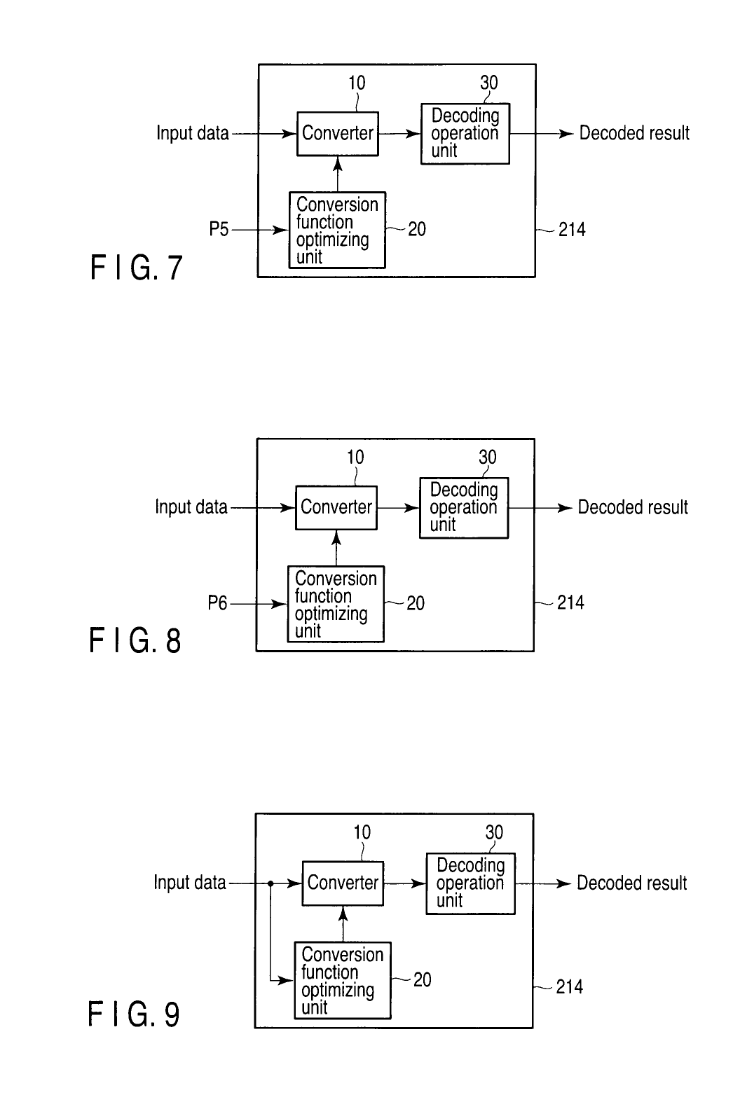

FIG. 7 is a block diagram showing the configuration of an error checking and correction unit (ECC unit) 214 of a memory system according to this fifth embodiment. In this case, the whole configuration of the memory system is the same as shown in FIG. 1. Basic matters described in FIG. 2 apply to this fifth embodiment. Moreover, the basic configuration shown in FIG. 7 is the same as FIG. 3. Others, basic matters described in the first embodiment apply to this fifth embodiment. Therefore, the explanation about matters described in the first embodiment is omitted.

According to this embodiment, a conversion function optimizing unit 20 is supplied with information P5 related to a history of an error generation when a semiconductor memory 100 is decoded. As seen from the foregoing description, the characteristic of a semiconductor memory 100 has an age-based change. For this reason, the characteristic of a semiconductor memory 100 is reduced due to an age-based change. As a result, the probability that an error bit is detected in decoding becomes high. Namely, there is a correlation between a history of an error generation (a history of the number of error bits) in decoding and the generation probability characteristic shown in FIGS. 2(a) and 2(b). So, the conversion function optimizing unit 20 optimizes a conversion function (conversion characteristic) of a converter 10 in accordance with a history of an error generation when a semiconductor memory 100 is decoded. Specifically, the conversion function optimizing unit 20 is previously provided with a plurality of conversion tables as well as the first embodiment. Further, the optimal conversion table for the converter 10 is set in accordance with the foregoing history of an error generation. The detailed configuration of the conversion table is the same as the first embodiment.

As described above, according to this embodiment, the optimal conversion table for the converter 10 is set in accordance with a history of an error generation when a semiconductor memory 100 is decoded. Then, input data from the semiconductor memory 100 is converted to a suitable log likelihood ratio. In general, there is a correlation between a generation probability of a read value from a memory and the foregoing history of an error generation. For this reason, the memory system of this embodiment is used, and thereby, it is possible to input a suitable log likelihood ratio to a decoding operation unit 30, and to accurately execute a decoding operation of an error correcting code. Therefore, a sufficient decoding performance is obtained. Moreover, according to this embodiment, the optimal conversion table (conversion function) for the converter 10 is set before decoding as well as the first embodiment; therefore, this serves to reduce processing time and energy consumption.

### Sixth Embodiment

FIG. 8 is a block diagram showing the configuration of an error checking and correction unit (ECC unit) 214 of a memory system according to this sixth embodiment. In this case, the whole configuration of the memory system is the same as shown in FIG. 1. Basic matters described in FIG. 2 apply to this sixth embodiment. Moreover, the basic configuration shown in FIG. 8 is the same as FIG. 3. Others, basic matters described in the first embodiment apply to this sixth embodiment. Therefore, the explanation about matters described in the first embodiment is omitted.

According to this embodiment, a conversion function optimizing unit 20 is supplied with information P6 related to a history of likelihood when a semiconductor memory 100 is decoded. As seen from the foregoing description, the characteristic of a semiconductor memory 100 has an age-based change. For this reason, the characteristic of a semiconductor memory 100 is reduced due to an age-based change. As a result, the likelihood in decoding becomes low. In other words, the likelihood of each decoded bit becomes low. Therefore, there is a correlation between a history of likelihood in decoding and the generation probability characteristic shown in FIGS. 2(a) and 2(b). So, the conversion function optimizing unit 20 optimizes a conversion function (conversion characteristic) of a converter 10 in accordance with a history of likelihood when a semiconductor memory 100 is decoded. Specifically, the conversion function optimizing unit 20 is previously provided with a plurality of conversion tables as well as the first embodiment. Further, the optimal conversion table for the converter 10 is set in accordance with the foregoing history of likelihood. The detailed configuration of the conversion table is the same as the first embodiment.

As described above, according to this embodiment, the optimal conversion table for the converter 10 is set in accordance with a history of likelihood when a semiconductor memory 100 is decoded. Then, input data from the semiconductor memory 100 is converted to a suitable log likelihood ratio. In general, there is a correlation between a generation probability of a read value from a memory and the foregoing history of likelihood. For this reason, the memory system of this embodiment is used, and thereby, it is possible to input a suitable log likelihood ratio to a decoding operation unit 30, and to accurately execute a decoding operation of an error correcting code. Therefore, a sufficient decoding performance is obtained. Moreover, according to this embodiment, the optimal conversion table (conversion function) for the converter 10 is set before decoding as well as the first embodiment; therefore, this serves to reduce processing time and energy consumption.

### Seventh Embodiment

FIG. 9 is a block diagram showing the configuration of an error checking and correction unit (ECC unit) 214 of a memory system according to this seventh embodiment. In this case, the whole configuration of the memory system is the same as shown in FIG. 1. Basic matters described in FIG. 2 apply to this seventh embodiment. Moreover, the basic configuration shown in FIG. 9 is the same as FIG. 3. Others, basic matters described in the first embodiment apply to this seventh embodiment. Therefore, the explanation about matters described in the first embodiment is omitted.

According to this embodiment, a conversion function optimizing unit 20 is supplied with information related to a variation of input data to a converter 10. As seen from the foregoing description, the characteristic of a semiconductor memory 100 has an age-based change. For this reason, the characteristic of a semiconductor memory 100 is reduced due to an age-based change. As a result, a variation of input data increases. In other words, a variation of each distribution (A to D) of the generation probability shown in FIG. 2 increases. Therefore, there is a correlation between a variation of input data and the generation probability characteristic shown in FIGS. 2(a) and 2(b). So, the conversion function optimizing unit 20 optimizes a conversion function (conversion characteristic) of a converter 10 in accordance with a variation of input data of a semiconductor memory 100. Specifically, the conversion function optimizing unit 20 is previously provided with a plurality of conversion tables as well as the first embodiment. Further, the optimal conversion table for the converter 10 is set based on information related to the foregoing variation. The detailed configuration of the conversion table is the same as the first embodiment.

As described above, according to this embodiment, the optimal conversion table for the converter 10 is set in accordance with a variation of input data to a converter 10. Then, input data from the semiconductor memory 100 is converted to a suitable log likelihood ratio. In general, there is a correlation between a generation probability of a read value from a memory and the foregoing variation of input data. For this reason, the memory system of this embodiment is used, and thereby, it is possible to input a suitable log likelihood ratio to a decoding operation unit 30, and to accurately execute a decoding operation of an error correcting code. Therefore, a sufficient decoding performance is obtained. Moreover, according to this embodiment, the optimal conversion table (conversion function) for the converter 10 is set before decoding as well as the first embodiment; therefore, this serves to reduce processing time and energy consumption.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A memory system comprising:
a semiconductor memory;
a converter configured to convert an input data input from the semiconductor memory into a log likelihood ratio based on a conversion function;
a conversion function optimizing unit configured to optimize the conversion function used for the converter; and
a decoding operation unit configured to input the log likelihood ratio output from the converter to execute a decoding operation of an error correcting code,
wherein the conversion function optimizing unit optimizes the conversion function based on information related to a number of times of using the semiconductor memory.

2. The system according to claim 1, wherein the semiconductor memory is a NAND flash memory.

3. A memory system comprising:
a semiconductor memory;
a converter configured to convert an input data input from the semiconductor memory into a log likelihood ratio based on a conversion function;
a conversion function optimizing unit configured to optimize the conversion function used for the converter; and
a decoding operation unit configured to input the log likelihood ratio output from the converter to execute a decoding operation of an error correcting code,
wherein the conversion function optimizing unit optimizes the conversion function based on information related to an elapsed time after the semiconductor memory is manufactured.

4. The system according to claim 3, wherein the semiconductor memory is a NAND flash memory.

5. A memory system comprising:
a semiconductor memory;
a converter configured to convert an input data input from the semiconductor memory into a log likelihood ratio based on a conversion function;
a conversion function optimizing unit configured to optimize the conversion function used for the converter; and
a decoding operation unit configured to input the log likelihood ratio output from the converter to execute a decoding operation of an error correcting code,
wherein the conversion function optimizing unit optimizes the conversion function based on information related to an elapsed time after write to the semiconductor memory is carried out.

6. The system according to claim 5, wherein the semiconductor memory is a NAND flash memory.

7. A memory system comprising:
a semiconductor memory;
a converter configured to convert an input data input from the semiconductor memory into a log likelihood ratio based on a conversion function;
a conversion function optimizing unit configured to optimize the conversion function used for the converter; and
a decoding operation unit configured to input the log likelihood ratio output from the converter to execute a decoding operation of an error correcting code,
wherein the conversion function optimizing unit optimizes the conversion function based on information related to a number of write times until a desired write voltage is obtained when write to the semiconductor memory is carried out.

8. The system according to claim 7, wherein the semiconductor memory is a NAND flash memory.

9. A memory system comprising:
a semiconductor memory;
a converter configured to convert an input data input from the semiconductor memory into a log likelihood ratio based on a conversion function;
a conversion function optimizing unit configured to optimize the conversion function used for the converter; and
a decoding operation unit configured to input the log likelihood ratio output from the converter to execute a decoding operation of an error correcting code,
wherein the conversion function optimizing unit optimizes the conversion function based on information related to a history of an error generation when the semiconductor memory is decoded.

10. The system according to claim 9, wherein the semiconductor memory is a NAND flash memory.

11. A memory system comprising:
a semiconductor memory;
a semiconductor memory;
a converter configured to convert an input data input from the semiconductor memory into a log likelihood ratio based on a conversion function;
a conversion function optimizing unit configured to optimize the conversion function used for the converter; and
a decoding operation unit configured to input the log likelihood ratio output from the converter to execute a decoding operation of an error correcting code,
wherein the conversion function optimizing unit optimizes the conversion function based on information related to a history of a likelihood when the semiconductor memory is decoded.

12. The system according to claim 11, wherein the semiconductor memory is a NAND flash memory.

13. A memory system comprising:
a semiconductor memory;
a converter configured to convert an input data input from the semiconductor memory into a log likelihood ratio based on a conversion function;
a conversion function optimizing unit configured to optimize the conversion function used for the converter; and
a decoding operation unit configured to input the log likelihood ratio output from the converter to execute a decoding operation of an error correcting code,
wherein the conversion function optimizing unit optimizes the conversion function based on information related to a variation of the input data.

14. The system according to claim 13, wherein the semiconductor memory is a NAND flash memory.
